(19) United States
(12) Patent Application Publication
(10) Pub. No.: US 2023/0079277 A1
(43) Pub. Date: Mar. 16, 2023

(54) SYSTEMS AND METHODS FOR THERMOELECTRIC COOLING OF OPTICAL PORT

(71) Applicant: Dell Products L.P., Round Rock, TX (US)

(72) Inventors: Yuan CHEN, Shanghai (CN); Xiaoliang ZHOU, Nantong City (CN)

(73) Assignee: Dell Products L.P., Round Rock, TX (US)

(21) Appl. No.: 17/487,462

(22) Filed: Sep. 28, 2021

(30) Foreign Application Priority Data
Sep. 14, 2021 (CN) 202111077147.7

(51) Int. Cl. H01L 23/38

(52) U.S. Cl. CPC H01L 23/38

(57) ABSTRACT

A system may include a heat-generating component and a thermoelectric cooler thermally coupled to the heat-generating component and arranged such that when an electrical parameter is applied to the thermoelectric cooler, a temperature gradient is created across the thermoelectric cooler in which a first side of the thermoelectric cooler proximate to the heat-generating component is at a lower temperature than a second side of the thermoelectric cooler opposite the first side and less proximate to the heat-generating component than the first side.

### TECHNICAL FIELD

The present disclosure relates in general to information handling systems, and more particularly to systems and methods for thermoelectric cooling of an information handling resource of an information handling system, including thermoelectric cooling of an optical port.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

An information handling system may have a network interface or other input/output (I/O) interface configured to receive an optical transceiver module (e.g., a small form-factor pluggable (SFP) transceiver, a quad small form-factor pluggable (QSFP) transceiver, and/or other module in accordance with the Open Compute Project (OCP) specification). Such transceiver modules often plug into “cages” disposed on an I/O interface card, which often reside in the rear of the information handling system in which hot air (e.g., at 55° C. to 65° C.) is exhausting from the system. Such temperatures are often near the upper limit of temperature requirements of optical transceiver modules.

In an attempt to reduce temperatures within optical transceiver modules, heatsinks have been implemented in fixed locations on cages disposed on I/O interface cards and configured to receive the optical transceiver modules. However, such transceivers are often limited and associated ports are often limited in their use of heatsinks, given space restrictions often allotted to optical transceivers and optical ports. As power consumption of optical transceivers increases from generation to generation, it may become increasingly difficult to adequately cool optical transceivers and optical ports using existing approaches.

### SUMMARY

In accordance with the teachings of the present disclosure, the disadvantages and problems associated with existing approaches to cooling optical networking components and other information handling resources may be reduced or eliminated.

In accordance with embodiments of the present disclosure, a system may include a heat-generating component and a thermoelectric cooler thermally coupled to the heat-generating component and arranged such that when an electrical parameter is applied to the thermoelectric cooler, a temperature gradient is created across the thermoelectric cooler in which a first side of the thermoelectric cooler proximate to the heat-generating component is at a lower temperature than a second side of the thermoelectric cooler opposite the first side and less proximate to the heat-generating component than the first side.

In accordance with these and other embodiments of the present disclosure, a method may include causing an electrical parameter to be applied to a thermoelectric cooler thermally coupled to a heat-generating component and arranged such that when the electrical parameter is applied to the thermoelectric cooler, a temperature gradient is created across the thermoelectric cooler in which a first side of the thermoelectric cooler proximate to the heat-generating component is at a lower temperature than a second side of the thermoelectric cooler opposite the first side and less proximate to the heat-generating component than the first side.

In accordance with these and other embodiments of the present disclosure, a method may include thermally coupling a thermoelectric cooler to a heat-generating component and arranged such that when an electrical parameter is applied to the thermoelectric cooler, a temperature gradient is created across the thermoelectric cooler in which a first side of the thermoelectric cooler proximate to the heat-generating component is at a lower temperature than a second side of the thermoelectric cooler opposite the first side and less proximate to the heat-generating component than the first side.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of selected components of an example information handling system, in accordance with embodiments of the present disclosure;

FIG. 2 illustrates a perspective view of an example optical transceiver module, in accordance with embodiments of the present disclosure;

FIG. 3 illustrates a perspective view of two instances of the example optical transceiver module shown in FIG. 2 inserted into respective optical ports of an I/O interface, in accordance with embodiments of the present disclosure; and

FIG. 4 illustrates a cross-sectional elevation view of an optical port and a thermoelectric cooler thermally coupled thereto, in accordance with embodiments of the present disclosure.

### DETAILED DESCRIPTION

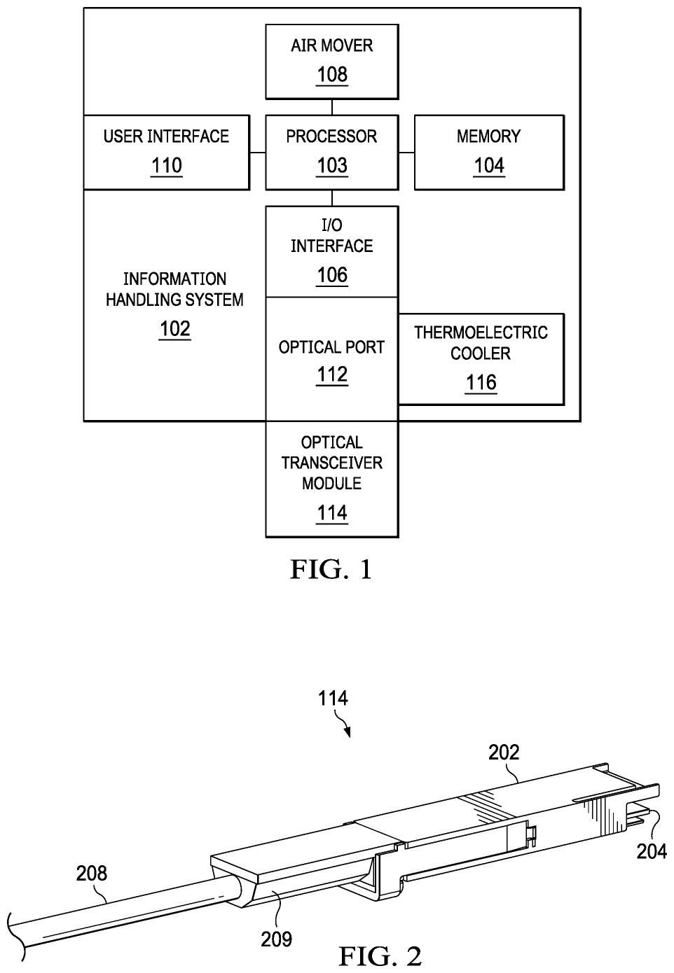

Preferred embodiments and their advantages are best understood by reference to FIGS. 1 through 4, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a personal digital assistant (PDA), a consumer electronic device, a network storage device, or any other suitable device and may vary in size, shape, performance, functionality, and price. The information handling system may include memory, one or more processing resources such as a central processing unit (“CPU”) or hardware or software control logic. Additional components of the information handling system may include one or more storage devices, one or more communications ports for communicating with external devices as well as various input/output (“I/O”) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, service processors, basic input/output systems (BIOSs), buses, memories, I/O devices and/or interfaces, storage resources, network interfaces, motherboards, and/or any other components and/or elements of an information handling system.

For the purposes of this disclosure, circuit boards may broadly refer to printed circuit boards (PCBs), printed wiring boards (PWBs), printed wiring assemblies (PWAs) etched wiring boards, and/or any other board or similar physical structure operable to mechanically support and electrically couple electronic components (e.g., packaged integrated circuits, slot connectors, etc.). A circuit board may comprise a substrate of a plurality of conductive layers separated and supported by layers of insulating material laminated together, with conductive traces disposed on and/or in any of such conductive layers, with vias for coupling conductive traces of different layers together, and with pads for coupling electronic components (e.g., packaged integrated circuits, slot connectors, etc.) to conductive traces of the circuit board.

FIG. 1 illustrates a functional block diagram of selected components of an example information handling system 102, in accordance with embodiments of the present disclosure. In some embodiments, information handling system 102 may be a personal computer (e.g., a desktop computer or a portable computer). In other embodiments, information handling system 102 may comprise a storage server for archiving data.

As depicted in FIG. 1, information handling system 102 may include a processor 103, a memory 104 communicatively coupled to processor 103, an input/output interface 106 communicatively coupled to processor 103, an air mover 108 communicatively coupled to processor 103, a user interface 110 communicatively coupled to processor 103, an optical port 112 communicatively coupled to I/O interface 106, and a thermoelectric cooler 116 thermally coupled to optical port 112.

Processor 103 may include any system, device, or apparatus configured to interpret and/or execute program instructions and/or process data, and may include, without limitation, a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in memory 104, air mover 108, and/or another component of information handling system 102.

Memory 104 may be communicatively coupled to processor 103 and may include any system, device, or apparatus configured to retain program instructions and/or data for a period of time (e.g., computer-readable media). Memory 104 may include random access memory (RAM), electrically erasable programmable read-only memory (EEPROM), a PCMCIA card, flash memory, magnetic storage, opto-magnetic storage, or any suitable selection and/or array of volatile or non-volatile memory that retains data after power to its associated information handling system 102 is turned off.

I/O interface 106 may comprise any suitable system, apparatus, or device operable to serve as an interface between information handling system 102 and one or more other external devices. For example, in some embodiments, I/O interface 106 may comprise a network interface configured to serve as an interface between information handling system 102 and information handling systems via a network, in which case I/O interface 106 may comprise a network interface card, or “NIC.”

Air mover 108 may include any mechanical or electro-mechanical system, apparatus, or device operable to move air and/or other gases in order to cool information handling resources of information handling system 102. In some embodiments, air mover 108 may comprise a fan (e.g., a rotating arrangement of vanes or blades which act on the air). In other embodiments, air mover 108 may comprise a blower (e.g., a centrifugal fan that employs rotating impellers to accelerate air received at its intake and change the direction of the airflow). In these and other embodiments, rotating and other moving components of system air mover 108 may be driven by a motor. In operation, air mover 108 may cool information handling resources of information handling system 102 by drawing cool air from the outside of and into an enclosure (e.g., chassis) housing the information handling resources, expel warm air from inside the enclosure to the outside of such enclosure, and/or move air across one or more heat sinks (not explicitly shown) internal to or external to the enclosure to cool one or more information handling resources.

User interface 110 may comprise any instrumentality or aggregation of instrumentalities by which a user may interact with information handling system 102. For example, user interface 110 may permit a user to input data and/or instructions into information handling system 102, and/or otherwise manipulate information handling system 102 and its associated components. User interface 110 may also permit information handling system 102 to communicate data to a user, e.g., by way of a display device.

Optical port 112 may comprise an electrical connector in the form of any suitable combination of a jack, a socket, and/or “cage” for receiving a corresponding connector of an optical transceiver module 114.

Optical transceiver module 114 may include any system, device, or apparatus that houses and includes an optical transceiver configured to convert an incoming optical signal into an equivalent electrical signal, and communicate such equivalent electrical signal to I/O interface 106, and also configured to receive an electrical signal from I/O interface 106, convert such electrical signal into an equivalent optical signal, and communicate such optical signal as an outgoing optical signal (e.g., via an optical cable, which may be integral to the same assembly as optical transceiver module 114). Optical transceiver module 114 may include an SFP transceiver, a QSFP transceiver, or any other suitable form factor.

Thermoelectric cooler 116 may comprise any suitable system, device, or apparatus configured to, in response to an electrical voltage applied to it, transfer heat from one side of thermoelectric cooler 116 to another side of thermoelectric cooler 116 in accordance with the thermoelectric effect (which may also be known as the Peltier effect, among other names). As described and shown in more detail below, thermoelectric cooler 116 may be arranged relative to optical port 112 such that the side of thermoelectric cooler 116 that cools when an electrical voltage is applied to it may be thermally coupled to a surface of optical port 112 and such that the side of thermoelectric cooler 116 that heats when an electrical voltage is applied to it may be within an airflow path of air flowing from air mover 108. Accordingly, heat may be transferred from optical port 112 to thermoelectric cooler 116, and from thermoelectric cooler 116 to air flowing proximate to thermoelectric cooler 116, thus cooling optical port 112 and also potentially cooling optical transceiver module 114 inserted into optical port 112.

In addition to processor 103, memory 104, I/O interface 106, air mover 108, user interface 110, optical port 112, optical transceiver module 114, and thermoelectric cooler 116, information handling system 102 may include one or more other information handling resources. Such an information handling resource may include any component system, device or apparatus of an information handling system, including without limitation, a processor, bus, memory, I/O device and/or interface, storage resource (e.g., hard disk drives), network interface, electro-mechanical device (e.g., fan), display, power supply, and/or any portion thereof. An information handling resource may comprise any suitable package or form factor, including without limitation an integrated circuit package or a printed circuit board having mounted thereon one or more integrated circuits.

FIG. 2 illustrates a perspective view of an example optical transceiver module 114 and cable 208 inserted into optical transceiver module 114, in accordance with embodiments of the present disclosure. In some embodiments, example optical transceiver module 114 depicted in FIG. 2 may be used to implement optical transceiver module 114 of FIG. 1. As shown in FIG. 2, optical transceiver module 114 may include a housing 202 for housing an optical transceiver 204 and one or more other components, a cable 208, and a strain relief feature 209. Housing 202 may comprise a metal enclosure configured to house and/or provide mechanical structure for optical transceiver 204, including mechanical features (e.g., guiding features) for aligning and/or mechanically securing optical transceiver 204 to I/O interface 106 via optical port 112.

Optical transceiver 204 may include any system, device, or apparatus configured to receive an incoming optical signal (e.g., via cable 208), convert the incoming optical signal into an equivalent electrical signal, and communicate such equivalent electrical signal to I/O interface 106 (e.g., via optical port 112), and also configured to receive an electrical signal from I/O interface 106 (e.g., via optical port 112), convert such electrical signal into an equivalent optical signal, and communicate such optical signal as an outgoing optical signal (e.g., via cable 208).

Cable 208 may include any suitable system, device, or apparatus capable of passing optical signals therethrough. For example, cable 208 may include one or more optical fibers surrounded by optically opaque material and/or material for protecting such one or more optical fibers. Such one or more optical fibers integral to cable 208 may be optically coupled to optical transceiver 204, thus enabling communication with optical transceiver 204 via such optical fibers.

Strain relief feature 209 may mechanically enclose cable 208 and may be formed from any suitable material that may be configured to provide strain relief to cable 208 while also providing support to the extension of housing 202.

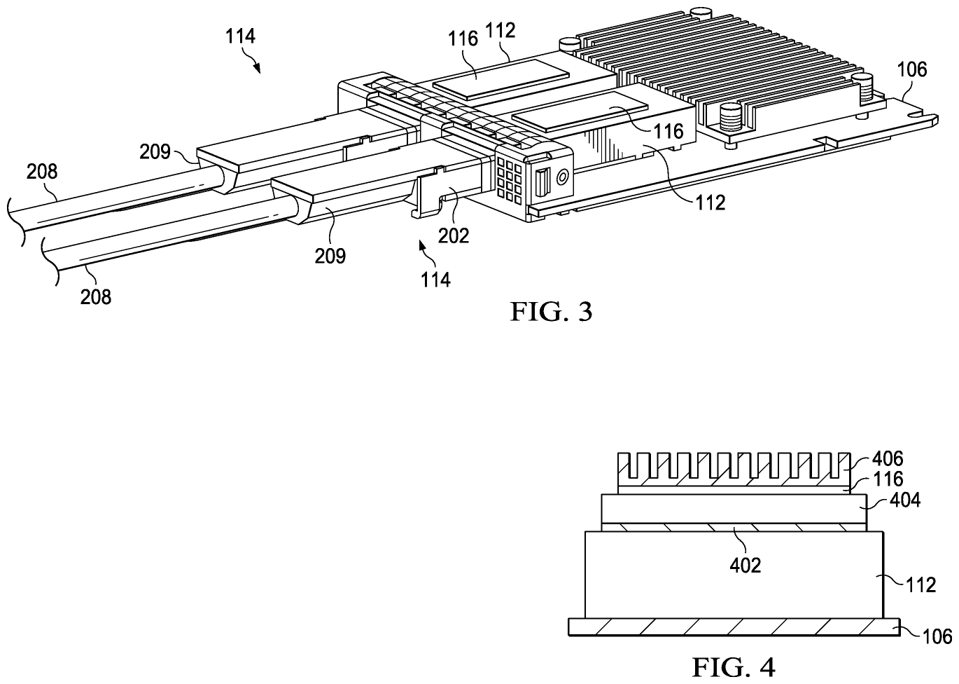

FIG. 3 illustrates a perspective view of two instances of example optical transceiver module 114 shown in FIG. 2 inserted into respective optical ports 112 of I/O interface 106, in accordance with embodiments of the present disclosure. As shown in FIG. 3, each of one or more thermoelectric coolers 116 may be thermally coupled to a surface of a respective optical port 112.

FIG. 4 illustrates a cross-sectional elevation view of an optical port 112 and a thermoelectric cooler 116 thermally coupled thereto, in accordance with embodiments of the present disclosure. As shown in FIG. 4, thermoelectric cooler 116 may be thermally coupled to optical port 112 via a thermal interface material 402 (e.g., silicon grease) disposed on a surface of optical port 112 and a neck 404 interfaced between thermal interface material 402 and thermoelectric cooler 116. Neck 404 may comprise a thermally conductive material (e.g., copper) and may be present such that direct contact between thermal interface material 402 and thermoelectric cooler 116 is not needed. Without the presence of neck 404, thermoelectric cooler 116 may not be resilient to repeated insertion and removal of optical transceiver module 114.

Although not depicted in FIG. 3 for purposes of clarity and exposition, in some embodiments a heatsink or other heat-rejecting media may be mechanically and thermally coupled to thermoelectric cooler 116 in order to dissipate heat (e.g., via air driven by a fan, blower, or other air mover) from the side of thermoelectric cooler 116 that is at a higher temperature.

Although FIGS. 3 and 4 do not depict electrical connections of thermoelectric cooler 116, a voltage may be applied across a bottom surface (e.g., the surface of thermoelectric cooler 116 most proximate to optical port 112) and a top surface (e.g., the surface of thermoelectric cooler 116 opposite of the bottom surface) in any suitable manner in order to induce the thermoelectric effect such that a temperature gradient forms between the bottom surface and the top surface, with the bottom surface being cooler than the top surface. For example, suitable electrically-conductive wires for applying such voltage may be coupled between a printed circuit board comprising I/O interface 106 and respective voltage terminals of thermoelectric cooler 116.

The various components depicted in FIG. 4 may be mechanically coupled to one another via one or more mechanical clips, one or more mechanical brackets, one or more mechanical fasteners (e.g., screws), adhesive material, and/or any other suitable mechanism.

Although the foregoing contemplates the use of the methods and systems disclosed herein with respect to an optical port, the heat transfer techniques disclosed herein may be applied generally to cooling of any suitable information handling resource.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. A system, comprising:
a heat-generating component; and
a thermoelectric cooler thermally coupled to the heat-generating component and arranged such that when an electrical parameter is applied to the thermoelectric cooler, a temperature gradient is created across the thermoelectric cooler in which a first side of the thermoelectric cooler proximate to the heat-generating component is at a lower temperature than a second side of the thermoelectric cooler opposite the first side and less proximate to the heat-generating component than the first side.

2. The system of claim 1, wherein the electrical parameter comprises at least one of a voltage and a current.

3. The system of claim 1, wherein the heat-generating component comprises an information handling resource.

4. The system of claim 3, wherein the information handling resource comprises an optical port.

5. The system of claim 1, wherein the thermoelectric cooler is thermally coupled to the heat-generating component via:
a thermal interface material applied to a surface of the heat-generating component; and
a neck interfaced between the thermal interface material and the thermoelectric cooler.

6. A method, comprising:
causing an electrical parameter to be applied to a thermoelectric cooler thermally coupled to a heat-generating component and arranged such that when the electrical parameter is applied to the thermoelectric cooler, a temperature gradient is created across the thermoelectric cooler in which a first side of the thermoelectric cooler proximate to the heat-generating component is at a lower temperature than a second side of the thermoelectric cooler opposite the first side and less proximate to the heat-generating component than the first side.

7. The method of claim 6, wherein the electrical parameter comprises at least one of a voltage and a current.

8. The method of claim 6, wherein the heat-generating component comprises an information handling resource.

9. The method of claim 8, wherein the information handling resource comprises an optical port.

10. The method of claim 6, wherein the thermoelectric cooler is thermally coupled to the heat-generating component via:
a thermal interface material applied to a surface of the heat-generating component; and
a neck interfaced between the thermal interface material and the thermoelectric cooler.

11. A method, comprising
thermally coupling a thermoelectric cooler to a heat-generating component and arranged such that when an electrical parameter is applied to the thermoelectric cooler, a temperature gradient is created across the thermoelectric cooler in which a first side of the thermoelectric cooler proximate to the heat-generating component is at a lower temperature than a second side of the thermoelectric cooler opposite the first side and less proximate to the heat-generating component than the first side.

12. The method of claim 11, wherein the electrical parameter comprises at least one of a voltage and a current.

13. The method of claim 11, wherein the heat-generating component comprises an information handling resource.

14. The method of claim 13, wherein the information handling resource comprises an optical port.

15. The method of claim 11, wherein thermally coupling the thermoelectric cooler to the heat-generating component comprises:
applying a thermal interface material a surface of the heat-generating component; and
interfacing a neck between the thermal interface material and the thermoelectric cooler.
